(19) United States
(12) Patent Application Publication
(10) Pub. No.: US 2025/0344342 A1
(43) Pub. Date: Nov. 6, 2025

(54) MULTI-ZONE COLD PLATE

(71) Applicant: CoolIT Systems, Inc., Calgary (CA)

(72) Inventors: Xuerui Gu, Calgary (CA); Seyed Kamaleddin Mostafavi Yazdi, Calgary (CA)

(21) Appl. No.: 19/209,794

(22) Filed: May 16, 2025

Related U.S. Application Data
(63) Continuation-in-part of application No. 18/810,176, filed on Aug. 20, 2024.
(60) Provisional application No. 63/533,847, filed on Aug. 21, 2023.
(60) Provisional application No. 63/649,325, filed on May 18, 2024.

(51) Int. Cl. H05K 7/20

(52) U.S. Cl. CPC H05K 7/20254; H05K 7/20327

(57) ABSTRACT

A multi-zone cold plate includes at least first and second adjacent cooling zones. Each cooling zone has a heat-transfer chamber partly occupied by a corresponding heat-transfer core. Each cooling zone also has a corresponding inlet passage configured to convey a respective coolant to the respective cooling zone. Each cooling zone further has a corresponding outlet passage configured to convey the respective coolant from the corresponding cooling zone. A wall positioned between the first cooling zone and the second cooling zone prevents each respective coolant from mixing with the other. Such a multi-zone cold plate can provide a unique rate of cooling and/or a unique operating temperature to each cooling zone. Each unique rate of cooling or operating temperature can be tailored to correspond to specified operating parameters of heat-generating electronic devices that are positioned close to each other.

### CROSS-REFERENCE TO RELATED APPLICATIONS

This application claims benefit of and priority from U.S. Provisional Patent Application No. 63/649,325, filed May 18, 2024, and is a continuation-in-part of U.S. patent application Ser. No. 18/810,176, filed Aug. 8, 2024, which claims benefit of and priority from U.S. Provisional Patent Application No. 63/533,847, filed Aug. 21, 2023, the contents of which patent applications are hereby incorporated by reference to the same extent as if reproduced in full, for all purposes.

### FIELD

This application and the subject matter disclosed herein (collectively referred to as the “disclosure”) pertain to heat-transfer between a solid and a liquid, and generally concern components that facilitate or provide heat transfer between a solid and a liquid, together with associated systems and methods.

### BACKGROUND INFORMATION

New generations of electronic components, such as, for example, memory components, microprocessors, graphics processors, and power electronics semiconductor devices, produce increasing amounts of heat when operating. In addition, electronic devices, such as, for example, servers, computers, game consoles, power electronics, communications and other networking devices, batteries, and so on, arrange electronic components in close proximity with each other. If the heat generated by operating such components is not removed at a sufficient rate, the components can overheat, decreasing their performance, reliability, or both, and in some cases such overheating can result in outright component damage or failure.

The prior art has addressed these challenges using air cooling, liquid cooling (e.g., involving liquid coolant, e.g., water, glycol, polyethylene glycol, etc.), or a combination thereof, to transfer and dissipate heat from electronic components to an ultimate heat sink, e.g., the atmosphere.

Conventional air cooling relies on natural convection or uses forced convection (e.g., a fan mounted near a heat producing component) to replace heated air with cooler ambient air around the component. Such air-cooling techniques can be supplemented with a conventional “heat sink,” which often is a plate of a thermally conductive material (e.g., aluminum or copper) placed in thermal contact with the heat-producing component. The heat sink can spread heat from the component to a larger area for dissipating heat to the surrounding air. Some heat sinks include “fins” to further increase the surface area available for heat transfer and thereby to improve the transfer of heat to the air. Some heat sinks include a fan to force air among the fins and are commonly referred to in the art as “active” heat sinks. Some have previously proposed removing heat from a plurality of heat-generating components arranged in close proximity with each other using a single, air-cooled heat sink.

### SUMMARY

This disclosure pertains to liquid-and two-phase cooling systems that transfer heat from one or more heat-generating components to a fluid (e.g., in a liquid state, a gaseous state, or a saturated mixture of liquid and gas) passing through a cold plate, or a plurality thereof, each having a plurality of microchannels through which the fluid passes to absorb heat, together with related methods and systems, such as, for example, principles and techniques described in U.S. Patent Application No. 63/533,847, filed Aug. 21, 2023, and U.S. Pat. No. 8,746,330, issued Jun. 10, 20214, which claims benefit of and priority from U.S. Provisional Patent Application No. 60/954,987, filed Aug. 9, 2007, the contents of which patent and patent applications are hereby incorporated by reference to the same extent as if reproduced in full, for all purposes.

Such liquid and two-phase cooling improves cooling performance compared to air cooling techniques described above, as many liquids, e.g., water, have significantly better heat transfer capabilities than air. FIG. 1 illustrates various components of a liquid cooling loop 100. The cooling loop 100 typically operates by (1) transferring heat, \dot{Q}ᵢₙ, from a heat-generating electronic component (not shown) to a cool liquid passing through a heat exchanger 110 (sometimes referred to in the art as a “cold plate” or a “heat sink”) placed in thermal contact with the heat-generating component, (2) transporting the heat absorbed by the liquid to a remote radiator 120, or heat rejector (sometimes referred to in the art generally as a “heat exchanger,” or a “liquid-to-liquid heat exchanger” if the heat is rejected to another liquid or a “liquid-to-air heat exchanger” if the heat is rejected to air), (3) dissipating the heat, \dot{Q}ₒᵤₜ, from the remote radiator to another medium (e.g., air or facility water passing through the remote radiator), and (4) returning cooled liquid to the heat exchanger (or heat sink).

According to an aspect, a multi-zone cold plate includes first and second adjacent cooling zones, and a wall positioned between the first cooling zone and the second cooling zone. Each cooling zone has a heat-transfer chamber partly occupied by a corresponding heat-transfer core. Each cooling zone also has a corresponding inlet passage configured to convey a respective coolant to the respective cooling zone. Each cooling zone further has a corresponding outlet passage configured to convey each respective coolant from the corresponding cooling zone. The wall prevents each respective coolant from mixing with the other.

Some disclosed multi-zone cold plates include cold plate base and a housing overlying the cold plate base. The cold plate base can define a fin group corresponding to the heat-transfer core of the first cooling zone.

The fin group can be a first fin group and the cold plate base can define a second fin group corresponding to the heat-transfer core of the second cooling zone.

The cold plate base can define the wall positioned between the first cooling zone and the second cooling zone.

The housing can define the wall positioned between the first cooling zone and the second cooling zone.

The wall positioned between the first cooling zone and the second cooling zone can be distinct from the housing and the cold plate base.

The cold plate base can be a first cold plate base. The multi-zone cold plate can also include a second cold plate base that defines a second fin group corresponding to the heat-transfer core of the second cooling zone. The housing can further overlie the second cold plate base.

The wall positioned between the first cooling zone and the second cooling zone can be distinct from the housing and the cold plate base.

The housing can define the wall positioned between the first cooling zone and the second cooling zone.

The housing can define a first inlet port to and a first outlet port from heat-transfer chamber of the first cooling zone. The housing further can define a second inlet port to and a second outlet port from the heat-transfer chamber of the second cooling zone.

The housing can be fused with the first fin group.

The housing can be fused with the first fin group and with the second fin group.

The multi-zone cold plate can include a third cooling zone having a heat-transfer chamber partly occupied by a corresponding third heat-transfer core.

The cold plate base further can define a third fin group corresponding to the third heat-transfer core.

The multi-zone cold plate can further include a third cooling zone having a third heat-transfer chamber partly occupied by a corresponding third heat-transfer core.

The multi-zone cold plate can further include a third cold plate base that defines a third fin group corresponding to the third heat-transfer core. The housing can further overlie the third cold plate base.

A cooling system includes a cold plate having first and second adjacent cooling zones and a wall positioned between the first cooling zone and the second cooling zone. Each cooling zone has a heat-transfer chamber partly occupied by a corresponding heat-transfer core. The cold plate defines a first inlet passage configured to convey a first coolant to the first cooling zone, a second inlet passage configured to convey a second coolant to the second cooling zone, a first outlet passage configured to convey the first coolant from the first cooling zone, and a second outlet passage configured to convey the second coolant from the second cooling zone. The wall prevents the first coolant from mixing with the second coolant. The cooling system also includes at least one heat exchanger configured to reject heat from the first coolant to another medium.

Such a cooling system can also include a cold-plate base defining a fin group corresponding to each heat-transfer core.

Such a cooling system can also include a cold-plate base corresponding to each respective heat-transfer core, and each respective cold-plate base can define a respective fin group.

The foregoing and other features and advantages will become more apparent from the following detailed description, which proceeds with reference to the accompanying drawings.

### BRIEF DESCRIPTION OF THE DRAWINGS

Referring to the drawings, wherein like numerals refer to like parts throughout the several views and this specification, aspects of presently disclosed principles are illustrated by way of example, and not by way of limitation.

FIG. 1 illustrates a closed liquid cooling loop. FIG. 2 illustrates an isometric view of an embodiment of a multi-zone cold plate having three zones.

FIG. 2A shows an isometric view from below a housing of the multi-zone cold plate shown in FIG. 2.

FIG. 3 illustrates a cross-sectional view of the multi-zone cold plate taken along line I-I in FIG. 2.

FIG. 4 shows an isometric view of a cold plate base for a multi-zone cold plate.

FIG. 4A shows an end-elevation view of the cold plate shown in FIG. 4.

FIG. 5 shows a cross-sectional view of the cold plate shown in FIGS. 3 and 4 taken along line II-II in FIG. 4.

FIG. 5A shows an end-elevation view of the cross-section shown in FIG. 5.

FIG. 6 shows an isometric, cross-sectional view of another embodiment of a multi-zone cold plate taken alone a line analogous to line I-I in FIG. 2.

FIG. 7 shows an isometric view of the cold plate base and fins from FIG. 6.

FIG. 8 shows an isometric, cross-sectional view of another embodiment of multi-zone cold plate taken alone a line analogous to line I-I in FIG. 2.

FIG. 9 shows the cold plate base and fins of the cold plate in FIG. 8 with the housing cover removed.

FIG. 9A shows an exploded view of the cold plate base and fins shown in FIG. 9.

FIG. 10 shows an isometric, cross-sectional view of yet another embodiment of a multi-zone cold plate taken alone a line analogous to line I-I in FIG. 2. FIG. 10A shows an isometric view of the cold plate base and fins of the cold plate in FIG. 10 with the housing cover removed.

### DETAILED DESCRIPTION

The following and other features and advantages will become more apparent from this detailed description, which proceeds with reference to the accompanying drawings. Presently disclosed cooling devices and systems provide further improved cooling performance compared to previously proposed cooling devices and systems. For example, in contrast to previously proposed techniques that provide a single-zone heat sink (or cold plate) placed in thermal contact with one heat-generating component or in contact with a plurality of closely arranged heat-generating components, disclosed multi-zone cold plates provide, for example, a plurality of separate chambers within a single liquid-or a refrigerant-cooled cold plate. In other embodiments, a multi-zone cold plate can provide a plurality of fluidly coupled chambers among a fluid network comprising a plurality of conduits and fluid connections that convey a flow of the fluid (sometimes referred to in the art as a “coolant” or a “refrigerant,” though “refrigerant” often, but not always, refers to a two-phase coolant within a vapor-compression system) among the fluidly coupled chambers.

Such multi-zone cold plates, whether fluidly isolated from each other, fluidly coupled with each other in series or parallel, or a combination thereof, can provide tailored rates of cooling to each of a plurality of closely spaced heat-generating components, e.g., according to each component's anticipated or actual rate of heat generation, as well as its specified upper threshold temperature, selected operating temperature, lower threshold temperature, or a combination thereof. For example, a high-power component might operate efficiently at a higher or lower temperature than a temperature at which a nearby capacitor or power transistor operates efficiently. In such instances, coupling a single-zone cold plate with each of the heat-generating components might not, and in many instances cannot, suitably maintain the components at their preferred or selected temperatures. Nevertheless, the closely positioned components might not leave sufficient room for each heat-generating component to be cooled by a corresponding, stand-alone cold plate.

A multi-zone cold plate can overcome these and other problems because a single cold plate with a plurality of cooling zones can occupy less space than a plurality of cold plates in the prior art. Further, each cooling zone can correspond to a given heat-generating component and its specified thermal operating parameters, each rate of heat generation and any of a variety of specified temperatures (e.g., a specified upper threshold temperature, a selected operating temperature, a lower threshold temperature, or a combination thereof). In some embodiments, a multi-zone cold plate reduces heat transfer between or among the plurality of cooling zones, e.g., by insulating each zone from one or more other zones. Such insulation can arise from increasing a conductive thermal resistance from one zone to another zone, as well as by placing a physical barrier between cooling chambers of adjacent zones, e.g., to prevent coolant in one chamber from mixing with a coolant in an adjacent chamber. Further, such a physical barrier can be formed of a less thermally conductive material, e.g., plastic, composite, or a lesser conductive metal, e.g., stainless steel, to inhibit heat transfer (e.g., by providing a larger temperature gradient) across the barrier from one zone to another zone.

Such a multi-zone cold plate can effectively cool a plurality of closely arranged heat-generating components, including, for example, processing units (e.g., graphics processing units (GPUs), central processing units (CPUs), power electronics devices (e.g., voltage regulators, capacitors, etc.), communication bridges (or chipsets), and memory devices.

Referring now to FIGS. 2 through 5A, a multi-zone cold plate can have, for example, three zones, with each zone having a heat-transfer chamber partly occupied by a heat-transfer core. As cold plates described in U.S. Pat. No. 8,746,330 have an inlet passage leading to a plurality of microchannels and an outlet passage from the microchannels, each zone of the multi-zone cold plate 200 in FIG. 2 has an inlet passage, a heat-transfer core (analogous to the region occupied by the fins and microchannels in the '330 patent), and an outlet passage. These and other features of each zone are now described.

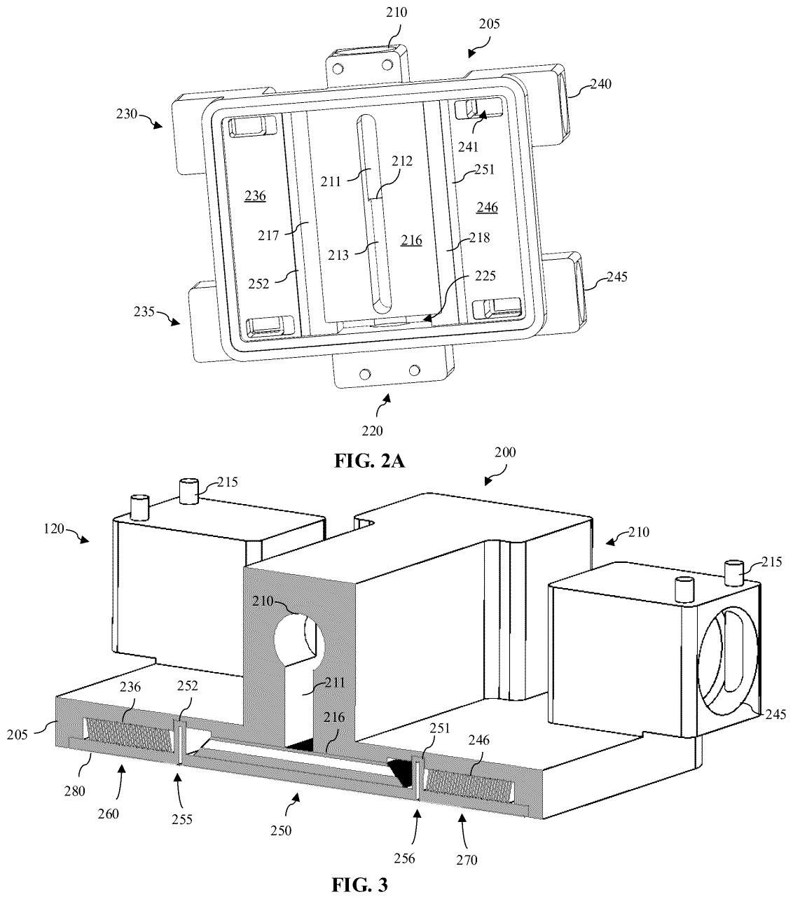

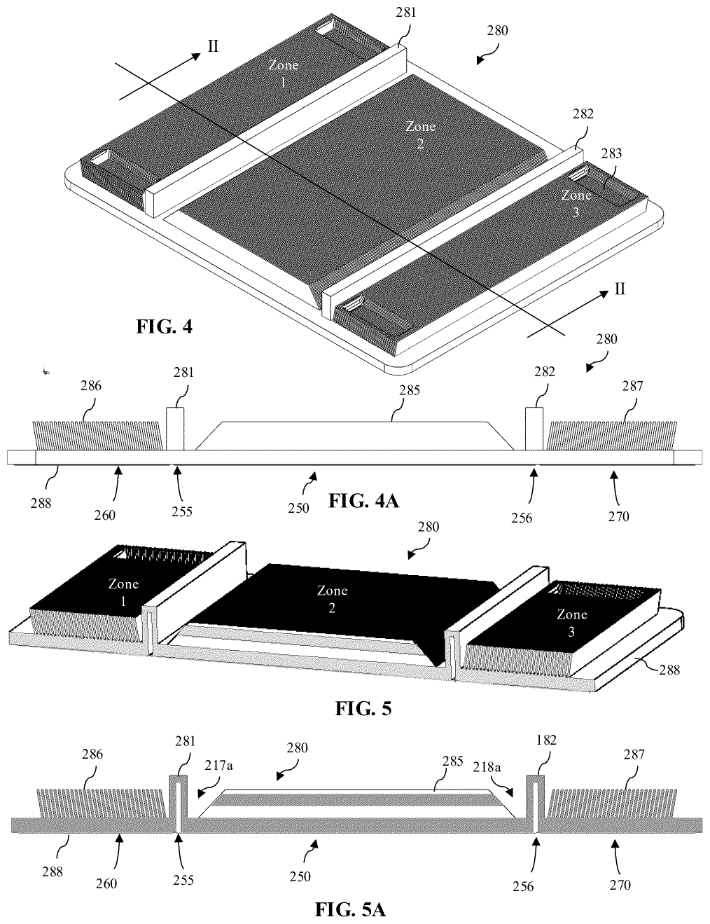

In FIG. 2, a housing 205 of the cold plate 200 is shown. The housing 205 defines an inlet port 210 to and an outlet port 220 from a central zone 250 (FIG. 3) corresponding to the Zone 2 heat-transfer core (FIGS. 4 and 5). The housing 205 also defines an inlet port 230 and an outlet port 235 corresponding to a first flanking zone 260 (FIG. 3) corresponding to the Zone 1 heat-transfer core (FIGS. 4 and 5). The housing 205 further defines an inlet port 240 and an outlet port 245 corresponding to a second flanking zone 270 (FIG. 3) corresponding to the Zone 3 heat-transfer core (FIGS. 4 and 5). Also shown are representative retainer pins 215 for retaining a port coupler (not shown) in the socket of each port. Such pins 215 can be inserted to the illustrated position after a port coupler has been inserted in the socket with a shoulder of the port coupler being positioned inboard of the pin, thereby inhibiting or preventing the port coupler from being easily removed from the socket.

As FIGS. 2, 2A and 3 show, the inlet port 210 and outlet port 220 corresponding to the central zone 250 are positioned between, respectively, the inlet ports 230, 240 and the outlet ports 235, 245 corresponding to the flanking zones 260, 270. With such an arrangement, the coolant flow through each zone can remain independent of (e.g., physically separate from) the coolant flow through each of the other zones, which in turn can allow the rate of cooling and the temperature of each zone to be independently tailored to a given component's (or group of components') specified operating parameters (e.g., rate of heat generated by the component(s), specified operating and threshold temperatures, etc.).

FIG. 2A shows an underside of the housing 205 shown in FIG. 2, revealing inlet and outlet passages for each zone, as well as features configured to be placed in opposed relation to other corresponding features for joining. The cross-section shown in FIG. 3 reveals portions of the laterally flanking zones 260, 270 and a portion of the inlet passage to the central zone 250.

Taking each zone in turn, the inlet passage for the central zone 250 extends from the inlet port 210 to an inlet manifold 211 partly defined by a recessed channel 213. The inlet port 210 has a recessed bore that extends from an open face (e.g., shown in FIG. 2) to an inner wall 212. As FIGS. 2A and 3 show, the recessed bore of the inlet port 210 intersects the recessed channel 231, providing a continuous interior open region overtop the microchannels of the heat-transfer core of the central zone 250, thereby defining the inlet manifold 211 that can distribute coolant among the microchannels of the heat-transfer core of the central zone 250. The housing 205 defines a major surface 216 that extends around an outer perimeter of the recessed channel 213 and can be positioned overtop the microchannels of the central zone 250 to close off the microchannels between the inlet manifold 211 and the opposed ends of the microchannels, which open to flanking manifolds 217, 218 (FIG. 2A). The open regions of the flanking manifolds 217, 218 are continuous with the open region of the recessed region 225, which in turn is continuous with the open bore defined by the outlet port 220. Accordingly, the outlet passage of the central zone 250 extends from the ends of the microchannels opening to the flanking manifolds 217, 218 to the outlet port 220, and extends through the manifolds and the open recessed region 225.

The laterally flanking zones 260, 270 also have respective inlet passages and outlet passages. Since the flanking zones 260, 270 have similar or identical passages throughout, details described in regard to one of the zones 260, 270 will be understood to apply to the other of the zones, unless otherwise noted. For both flanking zones, an open interior passage 241 extends from each respective major surface 236, 246 to each respective inlet port 230, 240. Analogous open interior passages extend from each respective major surface 236, 246 to each respective outlet port 235, 245. Regarding the flanking zone 270 (FIG. 3), the inlet passage extends from the inlet port 240 to the aperture in the major surface 246 defined by the passage 241, allowing coolant entering the inlet port 240 to flow directly to the microchannels of the heat-transfer core for the zone 270. In FIG. 4, the fins defining the microchannels define a recessed groove 283 extending transversely relative to the fins, which facilitates distribution of coolant among the microchannels as the coolant exits the passage 241. Similarly, the outlet passage extends from the microchannel outlets through the passage (analogous to passage 241) to the outlet port 245. The fins also define a recessed groove analogous to the recess 283 to facilitate collection of coolant from among the microchannels as it passes from the microchannels into the passageway on its way to the outlet port 245.

FIG. 4 shows an isometric view of a cold plate base 280 for the multi-zone cold plate 200. The base 280 has a plurality of fin groups 285, 286, 287 (FIG. 4A) extending from the base plate 288 and defining the microchannels for each zone. As revealed by the cross-sectional view in FIG. 5, the fins of each fin group can be oriented parallel to each other within the same zone and transverse relative to the fins in one or more other zones. For example, the fins of fin group 285 (corresponding to the central zone 250) can be oriented to extend transverse relative to the inlet manifold 211, e.g., from one end adjacent one laterally flanking zone 260 to an opposite end positioned adjacent the other laterally flanking zone 270, or vice versa. The fins of fin group 286 in laterally flanking zone 260 or the fins of fin group 287 in laterally flanking zone 270, or both, can be oriented at, for example, 90-degrees to the fins of fin group 285 in the central zone 250.

In some embodiments, a multi-zone cold plate reduces heat transfer between or among the plurality of cooling zones, e.g., by insulating each zone from one or more other zones. Such insulation can arise from increasing a conductione thermal resistance from one zone to another zone, as well as by placing a physical barrier between cooling chambers of adjacent zones, e.g., to prevent coolant in one chamber from mixing with a coolant in an adjacent chamber. Further, such a physical barrier can be formed of a less thermally conductive material, e.g., plastic, composite, or a lesser conductive metal, e.g., stainless steel, to inhibit heat transfer (e.g., by providing a larger temperature gradient) across the barrier from one zone to another zone.

The base 280 includes a base plate 288 with walls 281, 282 extending from the base plate 288 and defining physical barriers between the central zone 250 and the laterally flanking zones 260, 270, respectively. The walls 281, 282 can prevent the coolant passing through each zone 250, 260, 270 from mixing with coolant passing through the other zones. The walls 281, 282 can be continuous and monolithic with the base 280 or they can be inserted, e.g., press-fit into the base. The material of the walls 281, 282 can be the same as or different than the material of the base 280.

As FIGS. 3, 5 and 5A show, the walls 281, 282 have an inverted U-shape and extend into the groove 252, 251 (FIG. 2A), respectively, on the underside of the housing cover 205. The bars of the inverted U-shaped portion have a relatively thinner wall thickness than the rest of the cold plate base, and the bars of the inverted U-shaped portion are spaced apart from each other to define a gap 255, 256 (FIG. 5A). The thinner material and the gap 255, 256 increases the thermal conduction resistance through the base plate 288 between adjacent zones, and the vertically oriented bars of the inverted U-shaped portions provide a physical barrier to prevent mixing of coolant in one zone with the coolant in an adjacent zone (e.g., the walls 281, 282 prevent mixing of coolant passing through zone 250 with coolant passing through zone 260, or mixing of coolant passing through zone 250 with coolant passing through zone 270).

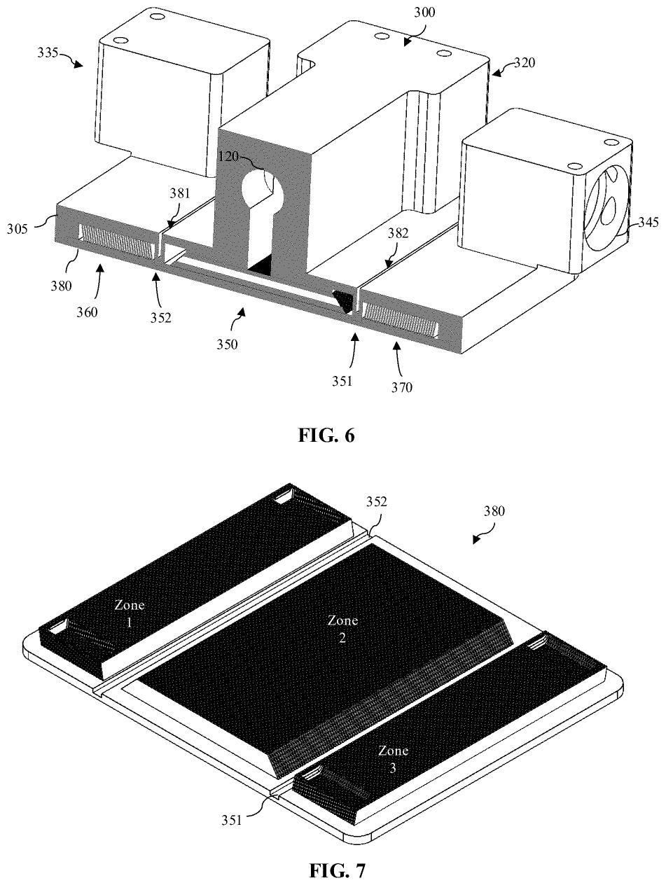

FIG. 6 shows a cross-sectional view of another embodiment of a multi-zone cold plate 300. Interior passageways for directing coolant through the cold plate 300 are substantially identical to the interior passageways for directing coolant through the cold plate 200. Thus, reference numerals for features of the multi-zone cold plate 300 are incremented by 100 relative to like features shown in connection with the multi-zone cold plate 200. However, in FIG. 6, the walls 381, 382 providing the insulation and barriers between zones 350, 360, 370 are respective U-shaped portions defined by the housing cover 305 as opposed to U-shaped portions defined by the cold plate base 280, as in FIG. 3.

In FIG. 6, a housing 305 of the cold plate 300 is shown. The housing 305 defines an inlet port (not shown) to and an outlet port 320 from a central zone 350 corresponding to the central heat-transfer core shown in FIG. 7. The housing 305 also defines an inlet port (not shown) and an outlet port 335 corresponding to a first flanking zone 360 corresponding to the left-most heat-transfer core in FIG. 7. The housing 305 further defines an inlet port (not shown) and an outlet port 345 corresponding to a second flanking zone 370 corresponding to the right-most heat-transfer core in FIG. 7.

FIG. 7 shows an isometric view of the cold plate base and fins from FIG. 6. In FIG. 7, the cold plate base defines a channel or groove between zones 1 and 2 and zones 2 and 3. The channel or groove in the cold-plate base 380 receives a lower extent of the U-shaped portion of the housing 305 (FIG. 6). Stated differently, the walls 381, 382 extend into the respective grooves 352, 351 defined, respectively, by the cold plate base 380. The bars of the inverted U-shaped portion have a relatively thinner wall thickness than the rest of the housing 305, and the bars of the inverted U-shaped portion are spaced apart from each other to define a gap (analogous to the gap 255, 256 in FIG. 5A). The thinner material and the gap increases the thermal conduction resistance through the housing 305 between adjacent zones, and the vertically oriented bars of the inverted U-shaped portions provide a physical barrier to prevent mixing of coolant in one zone with the coolant in an adjacent zone (e.g., the walls 381, 382 prevent mixing of coolant passing through zone 350 with coolant passing through zone 360, or mixing of coolant passing through zone 350 with coolant passing through zone 370).

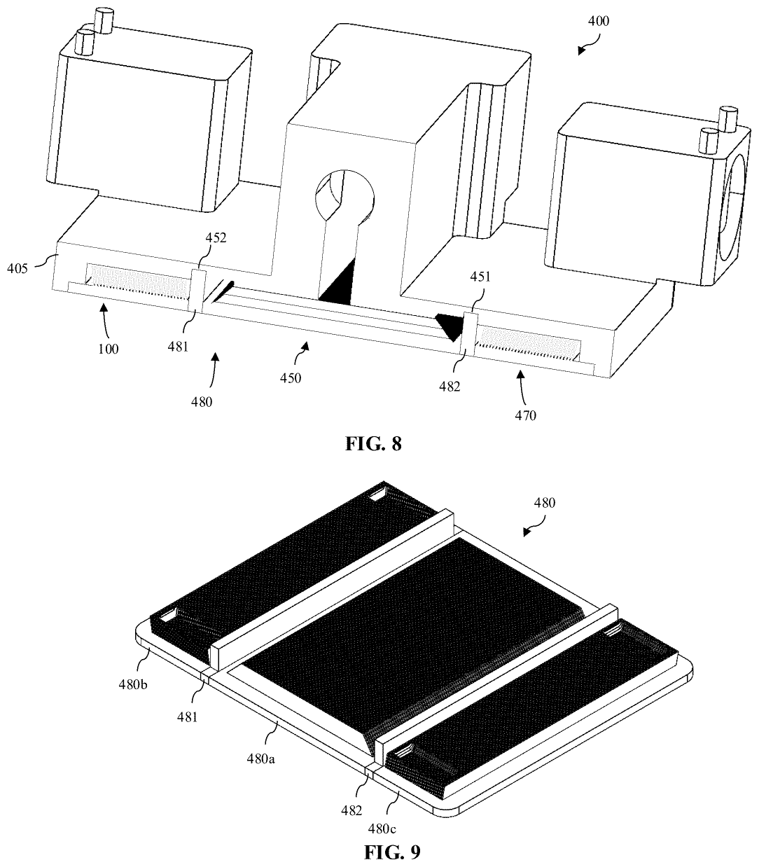

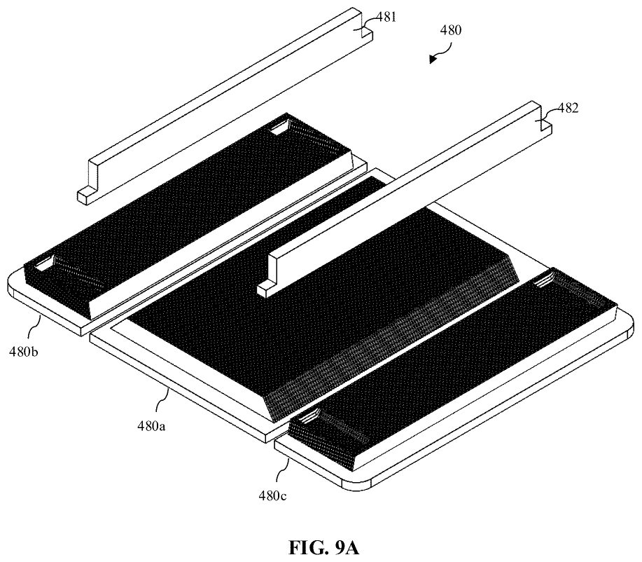

FIG. 8 shows another embodiment of multi-zone cold plate 400. FIG. 9 shows the cold plate 400 in FIG. 8 with the housing cover 405 removed. Interior passageways for directing coolant through the cold plate 400 are substantially identical to the interior passageways for directing coolant through the cold plate 200 and the cold plate 300. Thus, reference numerals for features of the multi-zone cold plate 400 are incremented by 100 relative to like features shown in connection with the multi-zone cold plate 300. Details of interior passages, as well as inlet and outlet ports for each zone 450, 460, 470 are omitted for succinctness and clarity. Nevertheless, the interior passages, as well as inlet and outlet ports for each zone 450, 460, 470, are substantially identical to the interior passages, as well as inlet and outlet ports for each zone 250, 260, 270 described above in connection with the cold plate 200.

In FIG. 8, the walls 481, 482 providing the insulation and barriers are inserts made of a less conductive material than that of the cold-plate base 480, fins and housing 405, e.g., the walls can be made of stainless steel while the other components can be made of a copper alloy. In FIG. 8, the cold plate base 480a, 480b, 480c for each zone 450, 460, 470, respectively, is separate from the cold plate base for the other zones, as shown by the exploded view in FIG. 9A.

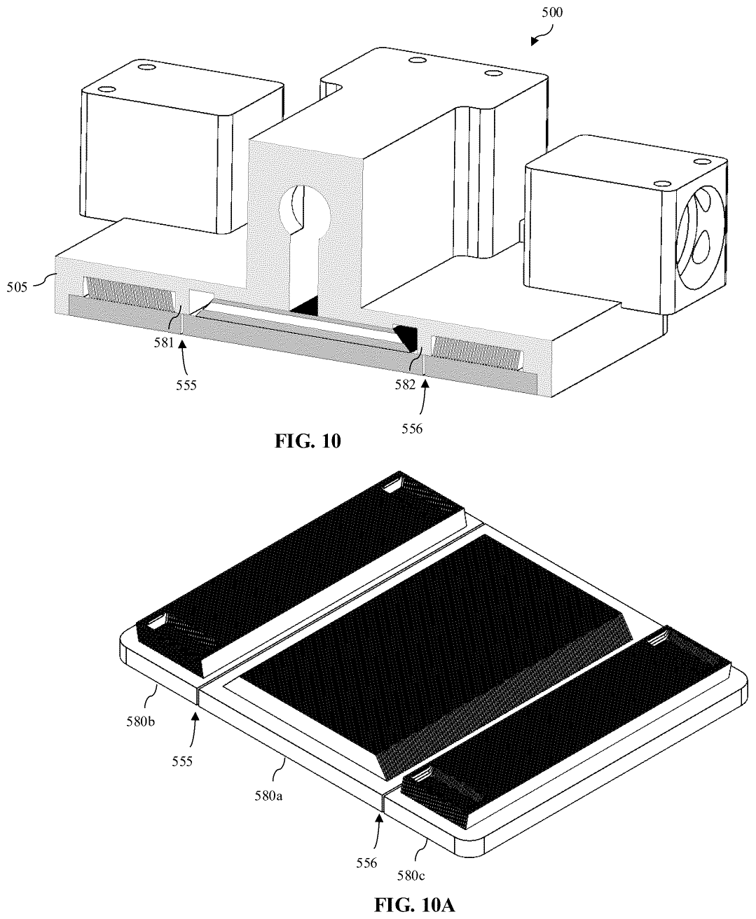

FIG. 10 shows yet another embodiment of a multi-zone cold plate 500. FIG. 10A shows the multi-zone cold plate 500 with the housing cover 505 removed. Interior passageways for directing coolant through the cold plate 500 are substantially identical to the interior passageways for directing coolant through the cold plates 200, 300, 400. Thus, reference numerals for features of the multi-zone cold plate 500 are incremented by 100 relative to like features shown in connection with the multi-zone cold plate 400. Details of interior passages, as well as inlet and outlet ports for each zone are omitted from the description of the cold plate 500 for succinctness and clarity. Nevertheless, the interior passages, as well as inlet and outlet ports for each zone, are substantially identical to the interior passages, as well as inlet and outlet ports for each zone 250, 260, 270 described above in connection with the cold plate 200.

Like the cold plate base 480a, 480b, 480c in FIG. 8, the cold plate 500 has separate cold plate base plates 580a, 580b, 580c for each zone. However, the housing cover 505 defines the walls 581, 582 that provide the insulation and barrier between adjacent zones. In FIG. 10, the housing cover 505 is made of a less conductive material than the base plates 580a, 580b, 580c and their fins.

Some disclosed cold plates provide a liquid-or a refrigerant-cooled cold plate for (1) directly cooling one or more, e.g., high-power, low-temperature (or both), heat-generating components; and (2) indirectly cooling one or more other, e.g., relatively-lower power, higher-temperature (or both), heat-generating components. One or more zones of a multi-zone cold plate can incorporate a split-flow technology as in U.S. Pat. No. 8,746,330 (e.g., a bifurcating or a convergent flow through the microchannels), and one or more other zones can provide a single-pass through a plurality of microchannels, e.g., from one end of the microchannels to an opposed, second end of the microchannels, or a convergent flow from opposed ends of the microchannels toward a center region of the microchannels, or a bifurcating flow.

An interface between each zone of a multi-zone cold plate and a corresponding heat-generating component can incorporate a thermal interface material, e.g., to enhance thermal contact between the opposed surfaces of the multi-zone cold plate and the corresponding heat-generating component. Thermal interface materials described herein can include thermal greases, thermal gap pads, thermal gels, thermal interface foils, etc. To facilitate variability in vertical height, e.g., from aggregated manufacturing tolerances, some thermal interface materials will desirably be able to compress to a greater degree than other thermal interfaces.

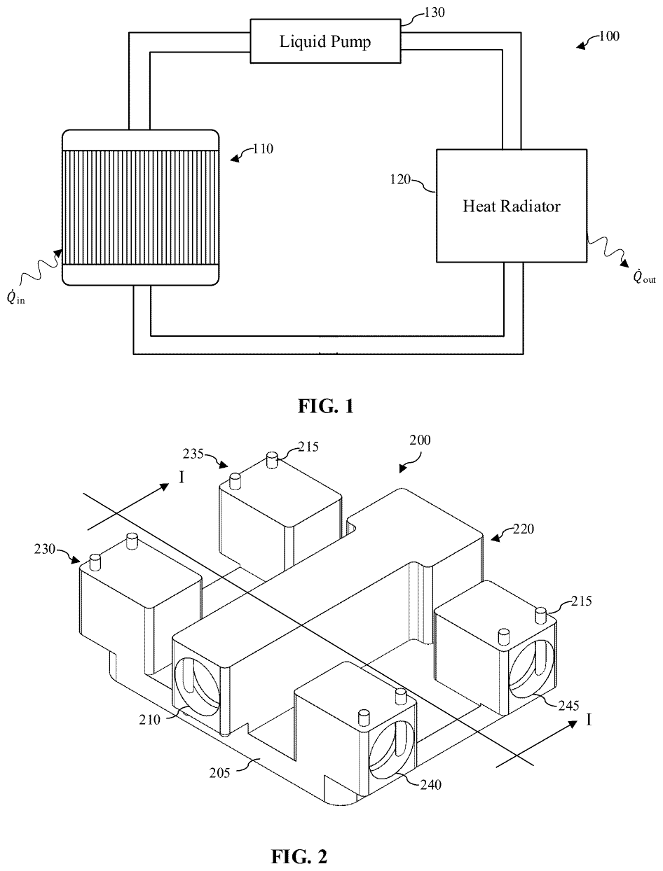

Referring again to the schematic illustration in FIG. 1, one or more multi-zone cold plates, e.g., as shown among FIGS. 2 to 10, can be substituted for the heat exchanger 110. Alternatively, one or more multi-zone cold plates, e.g., as shown among FIGS. 2 to 10, can be added to a cooling loop of the type depicted in FIG. 1. For example, the heat exchanger 110 shown in FIG. 1 may be placed in thermal contact with a processing component, and one or more multi-zone cold plates, e.g., as shown among FIGS. 2 to 10, can be fluidically coupled (in series or in parallel) with the heat exchanger 110. On reviewing this disclosure, a person of ordinary skill in the art will understand and appreciate the various modifications to fluid connections, pumping resources, and radiator configurations that such alternative arrangements could or would require in order to urge a sufficient flow of coolant through each heat exchanger/heat-exchanger assembly in a given cooling loop, as well as to reject absorbed heat from the coolant to another cooling medium.

Such cooling systems also can include a heat radiator configured to reject heat from the liquid coolant to another medium as the liquid coolant passes through the heat radiator, generally as described above in connection with FIG. 1. Such cooling systems also include a pump configured to urge the liquid coolant throughout a closed loop.

A cooling system as just described can be installed in or on an electronic device to cool a multi-chip module, or another plurality of heat-generating components operably assembled with a motherboard or an add-in card, alone or in combination with other heat-generating components e.g., memory components, memory controllers, processing units, power delivery devices, EEPROMs, etc. Moreover, a given electronic device, e.g., a server or a rack of servers, may have a plurality of motherboards, add-in cards, or modules, having operably mounted therewith a plurality of such heat-generating components, with each motherboards, add-in cards, or modules being cooled by an assembly of cold plates and thermal transfer plate as shown among FIGS. 2 to 10.

Structures that are in opposed relation to one another can be joined together to define a sealing (e.g., a state of being sealed) interface. A sealing interface may be formed between structures in opposed relation through bonding, adhesion and/or fusing. For example, one or more surfaces of the underside of the housing cover 205 (FIG. 2A), e.g., major surface 216, 236, 246 can define a sealing interface with the fins of the cold-plate base 280 by urging the two components together, e.g., sufficiently to inhibit or prevent coolant from bypassing the channels between the fins, or from leaking from one channel to another over top the fins. As an example, the major surface 216, 236, 246 can urge against distal edges of obliquely extending fins (i.e., distal from the base plate) with sufficient force to deflect the fins from an unloaded, at-rest orientation, ensuring sufficient interference between the fins and the major surface to prevent (or at least substantially inhibit) coolant from bypassing the microchannels or from leaking from one microchannel to an adjacent microchannel.

In some embodiments, the fins are so fabricated (e.g., skived) that their unloaded, at-rest orientation is oblique (e.g., transverse, but not perpendicular) to an upper surface of the base plate 280. As used herein, the phrase “unloaded, at-rest orientation” refers to an orientation of the fins relative to an upper surface (or other reference surface) of the base plate 280 before the housing 280 contacts the fins. By fabricating fins that are oblique to the upper surface (or other reference surface) of the base plate 280, a compressive load applied to the distal fin ends by the lower surface of the housing can cause the fins to deflect in a predictable and repeatable manner.

Such deflection can accommodate dimensional variations (e.g., dimensional tolerances) that accumulate among various features of the base plate 280, fins and housing 280. Moreover, accommodating such dimensional variations by fin deflection can ensure the fins contact the lower surface of the housing to inhibit or eliminate coolant leakage from one microchannel to another microchannel. Ensuring contact between the fins and the housing eliminates the need for a separate component, e.g., the un-numbered plate in FIGS. 2 to 4, the seal 130 in FIGS. 2 to 4, or both, in U.S. Pat. No. 8,746,330 used to inhibit or eliminate coolant leakage from one microchannel to another microchannel. Further, by accommodating such dimensional variations through fin deflection, e.g., by permitting the fins to interfere with the housing, contact between the fins and the housing can be ensured without requiring a separate joining technique to be applied between the fins and the housing.

Nevertheless, in other embodiments, one or more of the major surfaces 216, 236, 246 are joined with the fins of the cold plate base 280 using a high-temperature joining process (e.g., a brazing or soldering process). Such processes are also described in detail in co-pending U.S. patent application Ser. No. 18/810,176, filed Aug. 8, 2024. For example, distal edges of the fins can flare laterally outward to facilitate a high-temperature joining process. Such a flared distal edge provides an enlarged distal contact surface compared to raw distal edges that result when the fins are formed, e.g., with a skiving technique, further enhancing contact with a housing when assembled using a technique as described above in connection with the cold plate. Alternatively (or additionally), such enlarged distal edges can be joined or fused with another member, e.g., a housing, even when such joining techniques involve a flux or other joining additive that ordinarily might wick into small gaps, e.g., microchannels. Such fins are amenable to being brazed or otherwise fused (e.g., fusion welded or friction stir welded) together with a housing.

In still other embodiments, structures in opposed relation may optionally have a gasket or a seal positioned between opposed surfaces of the opposing structures, and the opposing structures may be fastened together using screws, clamps, rivets, pins, and/or other fasteners. Such gaskets and seals can enhance the ability of opposed faces to form a sealing interface between the joined structures. In still other embodiments, the structures in opposed relation may comprise complementary features that allow the structures in opposed relation to matingly engage with each other to form a sealing interface (with or without an intermediate gasket).

Some embodiments described herein can be used to cool one or more multi-chip modules, each having a plurality of active electronic components that generate heat while operating. Nonetheless, this disclosure is provided to enable a person skilled in the art to make or use embodiments of the disclosed principles. Embodiments other than those described herein or shown among the drawings are contemplated based on the principles disclosed herein, together with any attendant changes in configurations of the respective apparatus or changes in order of method acts described herein, without departing from the spirit or scope of this disclosure. Various modifications to the examples described herein will be readily apparent to those skilled in the art.

For example, concepts described herein can be used to cool a plurality of other types of heat-generating components that are combined into a functional module (e.g., as with a DIMM or another multichip module, e.g., a processing unit that includes one or more processing cores or chips, together with one or more voltage regulating components (so-called “VR components”) or other modules that include, for example, a so-called intermediate bus converter (IBC). For example, an assembly of cold plates as shown among FIGS. 2 to 27 can span across a plurality of such alternative components, even when the components have different heights from each other relative to the substrate to which they are mounted (e.g., by using concepts described herein, such as, for example, deforming a passive heat-transfer component or a compressible thermal interface material).

Directions and other relative references (e.g., up, down, top, bottom, left, right, rearward, forward, etc.) may be used to facilitate discussion of the drawings and principles herein, but are not intended to be limiting. For example, certain terms may be used such as “up,” “down,”, “upper,” “lower,” “horizontal,” “vertical,” “left,” “right,” and the like. Such terms are used, where applicable, to provide some clarity of description when dealing with relative relationships, particularly with respect to the illustrated embodiments. Such terms are not, however, intended to imply absolute relationships, positions, and/or orientations. For example, with respect to an object, an “upper” surface can become a “lower” surface simply by turning the object over. Nevertheless, it is still the same surface, and the object remains the same. As used herein, “and/or” means “and” or “or”, as well as “and” and “or.” Similarly, the foregoing description of illustrated cold-plate embodiments has described coolant flowing through each zone in a single direction, e.g., from an inlet port to an outlet port. However, embodiments where coolant flows in an opposite direction through disclosed multi-zone cold plates are contemplated by this description, including through the illustrated cold-plate embodiments. For embodiments where coolant flows in a direction opposite to that which is described herein in detail, a feature styled herein as an inlet port (or as an inlet passage) should be understood and interpreted as an outlet port (or an outlet passage). Similarly, a feature styled herein as an outlet port (or as an outlet passage) should be understood and interpreted as an inlet port (or an inlet passage). Further, an embodiment described herein as having or providing a bifurcating flow should be understood and interpreted as, alternatively, having or providing a convergent flow, as occurs when reversing direction of the flow of coolant through a bifurcating cold-plate embodiment.

Moreover, all patent and non-patent literature cited herein is hereby incorporated by reference in its entirety for all purposes.

And, those of ordinary skill in the art will appreciate that the exemplary embodiments disclosed herein can be adapted to various configurations and/or uses without departing from the disclosed principles. Applying the principles disclosed herein, it is possible to provide a wide variety of cooling devices for multi-chip modules, and related methods and systems to remove waste heat from such multi-chip modules. For example, the principles described above in connection with any particular example can be combined with the principles described in connection with another example described herein. Thus, all structural and functional equivalents to the features and method acts of the various embodiments described throughout the disclosure that are known or later come to be known to those of ordinary skill in the art are intended to be encompassed by the principles described and the features and acts claimed herein. Accordingly, neither the claims nor this detailed description shall be construed in a limiting sense, and following a review of this disclosure, those of ordinary skill in the art will appreciate the wide variety of cooling devices, and related methods and systems that can be devised using the various concepts described herein.

Moreover, nothing disclosed herein is intended to be dedicated to the public regardless of whether such disclosure is explicitly recited in the claims. No claim feature is to be construed under the provisions of 35 USC 112(f), unless the feature is expressly recited using the phrase “means for” or “step for”.

Reference to a feature in the singular, such as by use of the article “a” or “an” is not intended to mean “one and only one” unless specifically so stated, but rather “one or more”. Further, in view of the many possible embodiments to which the disclosed principles can be applied, we reserve the right to claim any and all combinations of features and technologies described herein as understood by a person of ordinary skill in the art, including the right to claim, for example, all that comes within the scope and spirit of the foregoing description, as well as the combinations recited, literally and equivalently, in any claims presented anytime throughout prosecution of this application or any application claiming benefit of or priority from this application, and more particularly but not exclusively in the claims appended hereto.

1. A multi-zone cold plate, comprising:
first and second adjacent cooling zones, wherein each cooling zone has a heat-transfer chamber partly occupied by a corresponding heat-transfer core, each cooling zone having a corresponding inlet passage configured to convey a respective coolant to the respective cooling zone, each cooling zone further having a corresponding outlet passage configured to convey each respective coolant from the corresponding cooling zone;
a wall positioned between the first cooling zone and the second cooling zone to prevent each respective coolant from mixing with the other.

2. The multi-zone cold plate according to claim 1, further comprising:
a cold plate base defining a fin group corresponding to the heat-transfer core of the first cooling zone; and
a housing overlying the cold plate base.

3. The multi-zone cold plate according to claim 2, wherein the fin group is a first fin group and the cold plate base defines a second fin group corresponding to the heat-transfer core of the second cooling zone.

4. The multi-zone cold plate according to claim 3, wherein the cold plate base defines the wall positioned between the first cooling zone and the second cooling zone.

5. The multi-zone cold plate according to claim 3, wherein the housing defines the wall positioned between the first cooling zone and the second cooling zone.

6. The multi-zone cold plate according to claim 3, wherein the wall positioned between the first cooling zone and the second cooling zone is distinct from the housing and the cold plate base.

7. The multi-zone cold plate according to claim 2, wherein cold plate base is a first cold plate base, wherein the multi-zone cold plate further comprises a second cold plate base that defines a second fin group corresponding to the heat-transfer core of the second cooling zone, wherein the housing further overlies the second cold plate base.

8. The multi-zone cold plate according to claim 7, wherein the wall positioned between the first cooling zone and the second cooling zone is distinct from the housing and the cold plate base.

9. The multi-zone cold plate according to claim 7, wherein the housing defines the wall positioned between the first cooling zone and the second cooling zone.

10. The multi-zone cold plate according to claim 2, wherein the housing defines a first inlet port to and a first outlet port from heat-transfer chamber of the first cooling zone, wherein the housing further defines a second inlet port to and a second outlet port from the heat-transfer chamber of the second cooling zone.

11. The multi-zone cold plate according to claim 2, wherein the housing is fused with the first fin group.

12. The multi-zone cold plate according to claim 3, wherein the housing is fused with the first fin group and with the second fin group.

13. The multi-zone cold plate according to claim 7, wherein the housing is fused with the first fin group and with the second fin group.

14. The multi-zone cold plate according to claim 3, further comprising a third cooling zone having a heat-transfer chamber partly occupied by a corresponding third heat-transfer core.

15. The multi-zone cold plate according to claim 14, wherein the cold plate base further defines a third fin group corresponding to the third heat-transfer core.

16. The multi-zone cold plate according to claim 7, further comprising a third cooling zone having a third heat-transfer chamber partly occupied by a corresponding third heat-transfer core.

17. The multi-zone cold plate according to claim 16, further comprising a third cold plate base that defines a third fin group corresponding to the third heat-transfer core, wherein the housing further overlies the third cold plate base.

18. A cooling system comprising:
a cold plate having first and second adjacent cooling zones and a wall positioned between the first cooling zone and the second cooling zone, wherein each cooling zone has a heat-transfer chamber partly occupied by a corresponding heat-transfer core, the cold plate defining a first inlet passage configured to convey a first coolant to the first cooling zone, a second inlet passage configured to convey a second coolant to the second cooling zone, a first outlet passage configured to convey the first coolant from the first cooling zone, and a second outlet passage configured to convey the second coolant from the second cooling zone, wherein the wall prevents the first coolant from mixing with the second coolant;
at least one heat exchanger configured to reject heat from the first coolant to another medium.

19. The cooling system according to claim 18, further comprising a cold-plate base defining a fin group corresponding to each heat-transfer core.

20. The cooling system according to claim 19, further comprising a cold-plate base corresponding to each respective heat-transfer core, each respective cold-plate base defining a respective fin group.
